(19) United States
(12) Patent Application Publication
(10) Pub. No.: US 2025/0224446 A1
(43) Pub. Date: Jul. 10, 2025

(54) CUSTOM WRAPPER CELL FOR HARDWARE TESTING

(71) Applicant: Google LLC, Mountain View, CA (US)

(72) Inventors: Wilson Pradeep, Bengaluru (IN); Veerabhadrarao Vasa, Bengaluru (IN); Vipin Kakkatt, Kozhikode (IN)

(21) Appl. No.: 18/853,301

(22) PCT Filed: Apr. 3, 2023
(86) PCT No.: PCT/US2023/017312

§ 371 Date: Oct. 1, 2024

(30) Foreign Application Priority Data
Apr. 1, 2022 (IN) 202241019939

(51) Int. Cl. G01R 31/317; G01R 31/3193

(52) U.S. Cl. CPC G01R 31/31704; G01R 31/31937

(57) ABSTRACT

Methods, systems, and apparatus, including computer programs encoded on computer storage media, for using custom wrapper cells. One of the methods includes receiving a hardware design having one or more functional components. If the hardware design has a functional component that is incompatible with a shared wrapper cell (SWC), a placeholder test register is added on a path to the functional component that is incompatible with a SWC. The placeholder test register is then converted to a custom wrapper cell.

### BACKGROUND

This specification relates to designing and testing integrated circuit devices.

Modem hardware systems are often designed to include test components that are used to verify the functionality of the system after fabrication. This approach is commonly known as design for testing (DFT). The complexity of modem devices increases the complexity of the required test components and test routines. Thus, for many systems, it is infeasible to test the entire system as a monolithic functional module. Instead, the design is partitioned into cores that can be tested independently.

These types of DFT devices rely on wrapper cells to perform the testing. A wrapper cell is a group of hardware components that are used to test a functional module of a hardware design. Wrapper cells are normally dedicated wrapper cells (DWC) or shared wrapper cells (SWC). A dedicated wrapper cell adds a dedicated test register that operates on a test clock that is separate and apart from a functional clock used during normal operation of the device. A shared wrapper cell on the other hand uses existing functional registers of the hardware design and thus operates on the functional clock.

Dedicated wrapper cells are typically simpler to implement. But they generally cannot be used to test synchronous inter-core interfaces because they run on a separate test clock, which is typically slower than the functional clock. A multi-core large system on a chip could have many synchronous inter-core interfaces. To achieve good test coverage and avoid a potentially large DPPM (defective parts per million) impact, it's imperative to enable at-speed testing of delay faults on these interfaces along the true functional access paths. Therefore, dedicated wrapper cells are unsuitable for testing delay faults and other errors on inter-core paths.

Shared wrapper cells operating on the functional clock can be used for testing some inter-core interfaces, but shared wrapper cells suffer from several limitations. In particular, the logic of the modules on the fanin or fanout cones of a shared wrapper cell must be completely defined. In other words, there cannot be any modules that operate as black boxes or abstract cells, for example, embedded random-access memories. In addition, shared wrapper cells cannot be used for testing integrated clock gating cells that enable or disable the functional clock to certain portions of the design.

These components may generally be referred to as non-scannable sequential elements (NSE) because they do not have a simple scan input for providing test inputs and a scan output for reading out test outputs.

As a result of these limitations, current DFT techniques fail to capture many design failures, particularly those that can only be identified when operating on the functional clock, such as those occurring along synchronous inter-core interfaces.

### SUMMARY

This specification describes techniques for using custom wrapper cells in hardware designs in order to provide at-speed testing for components that cannot be used with shared wrapper cells. In particular the custom wrapper cells can be used to test non-scannable sequential elements, including embedded memories and clock gating cells, at functional clock speeds.

Particular embodiments of the subject matter described in this specification can be implemented so as to realize one or more of the following advantages. Using custom wrapper cells as described in this specification allows true at-speed testing on synchronous interfaces and also significantly improves the testability on NSE paths. Besides providing the required isolation, CWC insertion adds controllability and observability on NSE paths allowing them to be tested at-speed as well. In addition, custom wrapper cells can be placed physically closer to NSEs and can have their clocks tapped from the same driver controlling clock input to the NSE. Given the minimal divergence, the clock skew delta between a CWC and an NSE can be expected to be negligible. This can help the tested path be much closer to the actual functional path.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1A is a diagram of an example dedicated wrapper cell.

FIG. 1B is a diagram of an example shared wrapper cell.

FIG. 1C is a diagram of an example custom wrapper cell.

FIG. 2A illustrates an example design that cannot use shared wrapper cells due to the presence of non-scannable sequential elements (NSEs).

FIG. 2B illustrates using custom wrapper cells in the presence of NSEs.

FIG. 3 is a flowchart of an example process for inserting a custom wrapper cell into a hardware design.

FIGS. 4A, 4B, 4C, and 4D illustrate the stages of an example process for inserting a custom wrapper cell into a hardware design.

Like reference numbers and designations in the various drawings indicate like elements.

### DETAILED DESCRIPTION

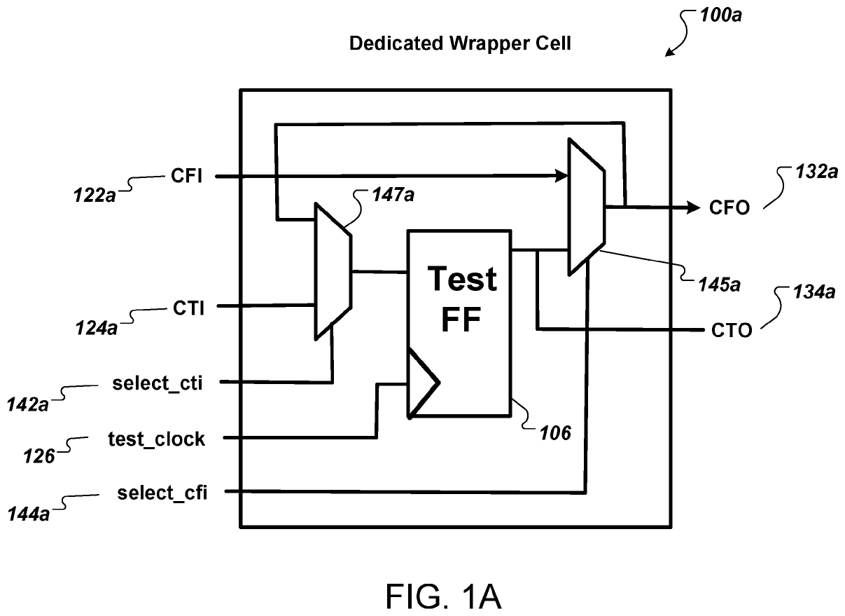

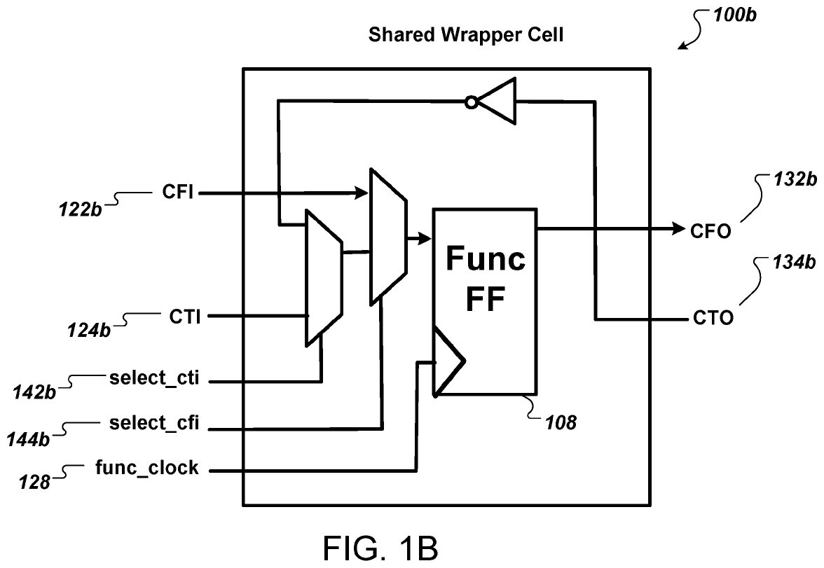

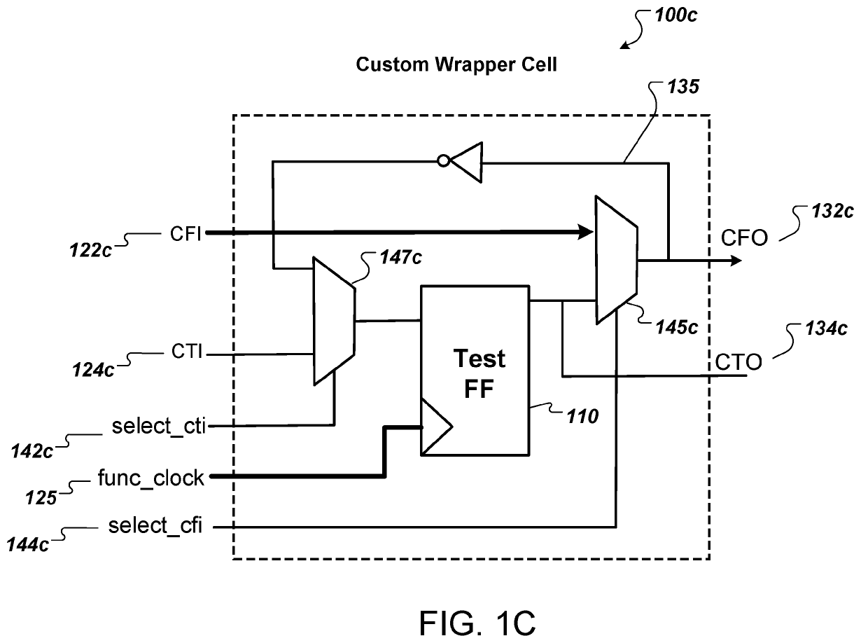

FIG. 1A is a diagram of an example dedicated wrapper cell (DWC) 100a. As shown, the DWC 100a has a dedicated test register 106, which works on a test clock signal 126, which is different than the clock signal used by the functional components of the device. The test clock signal 126 is typically slower than a functional clock used by the functional components of the device.

The DWC 100a includes a cell functional input (CFI) 122 that bypasses the dedicated test register 110 and is one of the inputs to an output multiplexor 145a. The DWC 100a also includes a cell test input (CTI) 124 that is an input to an input multiplexor 147a. A select cell test input (select_cti) signal 142a toggles between the dedicated test register 106 receiving the CTI 124a or a fed-back output of the output multiplexor 145a, which is another input to the input multiplexor 147a.

A select cell functional input (select_cfi) signal 144a toggles between the output multiplexor 145a providing the CFI 122a or the contents of the dedicated test register 106 as the cell functional output (CFO) 132a. Lastly, the DWC 100a includes a line such that the contents of the dedicated test register, the cell test output (CTO) 134a can bypass the output multiplexor 145a.

FIG. 1B is a diagram of an example shared wrapper cell (SWC) 100b. The SWC 100b does not have a dedicated test register. Instead, the SWC 100b uses an existing functional test register 108 that is a functional component of the device. Therefore, the functional test register 108 works on a functional clock signal 128. The SWC 100b provides as outputs a cell functional output (CFO) 132b and a cell test output (CTO) 134b. Both the CTO 132b and the CTO 134b return the contents of the functional register 108. The SWC 100b has a select cell test input signal 142b and select cell functional input 144b, which are used to control whether the functional register receives the CFI 122b or the CTI 124b.

FIG. 1C is a diagram of an example custom wrapper cell (CWC) 100c. As shown, the CWC 100c has a dedicated test register 110, which works on a functional clock signal 125 as opposed to a test clock signal used by DWCs. As described above, the functional clock typically operates at a faster speed than the test clock used by DWCs. The CWC 100c also includes an inverted loop back path 135 from an output multiplexor 145c to an input multiplexor 147c leading into the dedicated test register input 110, which enables at-speed transitions in launch or capture.

The CWC 100c includes a cell functional input (CFI) 122c that bypasses the dedicated test register 110 and is one of the inputs to the output multiplexor 145c. The CWC 100c also includes a cell test input (CTI) 124c that is another input to the input multiplexor 147c. A select cell test input (select_cti) signal 142c is provided as a control input to the input multiplexor 147c and toggles between the dedicated test register 110 receiving the CTI 124c or the inverted fed-back output of the output multiplexor 145c.

A select cell functional input (select_cfi) signal 144c is provided as a control input to the output multiplexor 145c and toggles between the output multiplexor 145c providing the CFI 122c or the contents of the dedicated test register 110 as the cell functional output (CFO) 132c. Lastly, the CWC 100c includes a line such that the contents of the dedicated test register, the cell test output (CTO) 134c, can bypass the output multiplexor 145.

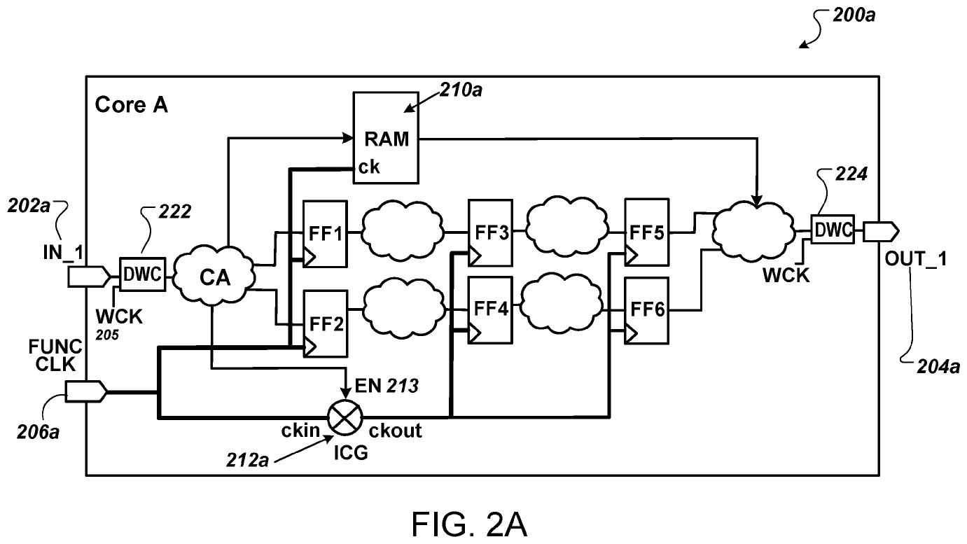

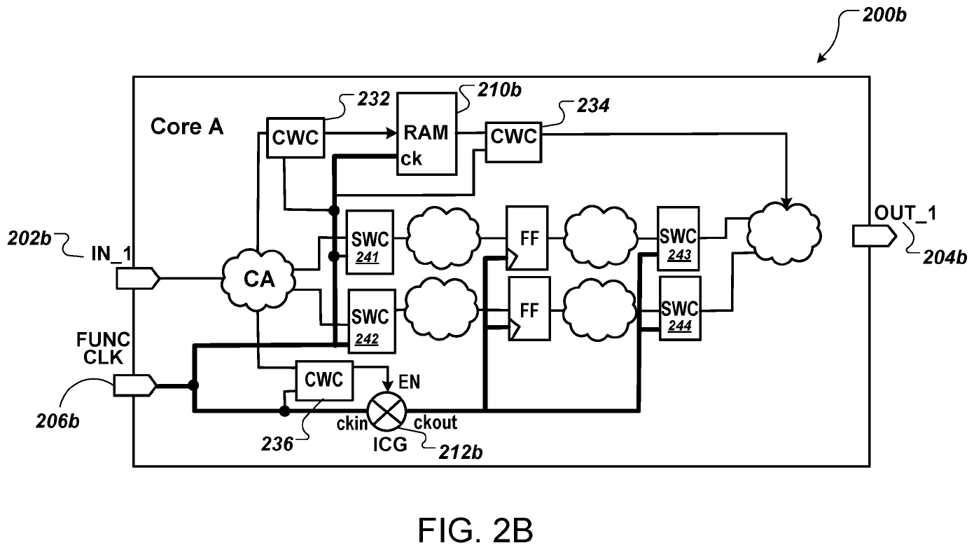

FIG. 2A illustrates an example design that cannot use shared wrapper cells (SWCs) due to the presence of non-scannable sequential elements (NSEs). The example core design 200a includes two NSEs in the fanout path of the input port 202. The NSEs include a RAM 210a and an integrated clock gating cell 212a having an enable 213 that is driven by the input port 202a.

Although SWCs are the preferable for wrapping functional ports along critical synchronous interfaces, there are several challenges and constraints which limit their usage. EDA tools typically used for core wrapper insertion have certain design requirements for identifying and mapping of SWCs, which can include one or more of the following: a) each flop in the fanin/fanout cone of the functional port should be a scannable flip-flop passing design rule checks for clock and reset controllability, b) the registers cannot be part of pre-existing scan segments or preserve logic, c) the logic in the fanin/fanout cone should be completely defined; there cannot be any black boxes or abstract cells such as embedded memories, or d) an input port should not drive the enable of an integrated clock gating cell.

This means that SWCs cannot be used in this example design 200a. Therefore the design 200a has two DWCs 222 and 224 at the root of the input port 202 and before the output port 204. respectively. But as described above, as DWCs run on a separate clock WCK 205, it is much harder to thoroughly test for timing vulnerabilities across synchronous interfaces when using DWCs.

FIG. 2B illustrates using custom wrapper cells (CWCs) in the presence of NSEs. In general, a system can place CWCs at the input or output of non-scannable sequential elements. As shown in FIG. 2B, the design 200b has three CWCs 232, 234, and 236 that are all driven by the functional clock 206b. The CWCs 232 and 234 can now be used to test both the inputs and outputs of the RAM 210b, as well as test the input of the integrated clock gating cell 212b. Although not shown, another CWC could be placed at the output of the ICG 212b. After the conversion of other functional registers to SWCs, the design 200b now also has four SWCs 241, 242, 243, and 244, to test the functional registers that are not located along the NSE paths.

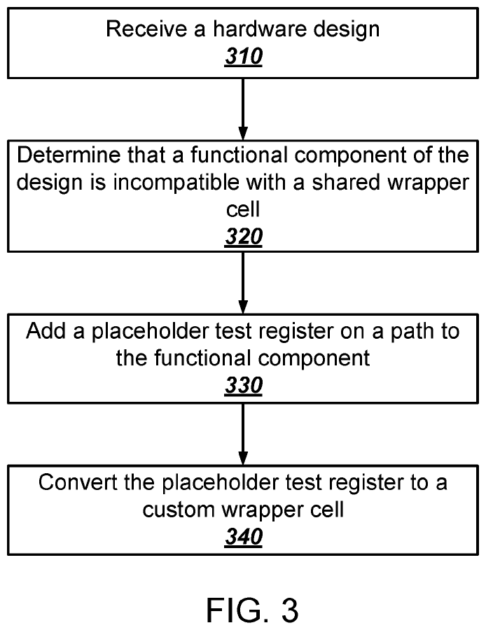

FIG. 3 is a flowchart of an example process for inserting a CWC into a hardware design. The example process can be performed by one or more computers in one or more locations and programmed in accordance with this specification. As one example, the example process could be performed by electronic design automation (EDA) tool software that is installed on a system of one or more computers.

The system receives a hardware design having one or more functional components (310). For example, the system can analyze a hardware design as part of an EDA process.

The system determines that the hardware design has a functional component that is incompatible with a shared wrapper cell (320). The functional component can be incompatible with a shared wrapper cell for a number of reasons, for example, because the fanin or fanout of the component includes a non-scannable sequential element. The NSE can for example be a component that does not have a scan input and/or a scan output for testing purposes, e.g., a random-access memory or an integrated clock gating cell.

The system adds a placeholder test register on a path to the functional component (330). As part of this process, the system can tap the same clock signal as the incompatible component in order to prepare the design for CWC insertion. By tapping the same clock signal as the incompatible component it is meant that the same functional clock as that used for the incompatible component is used for the placeholder test register. In some implementations, this step ensures that the design is compliant for SWC insertion as part of the next step, as SWCs also use the functional clock.

The system converts the placeholder test register to a custom wrapper cell (340). The system can use a module swap procedure to replace the placeholder test registers with custom wrapper cells. As part of this process, the system can first convert the placeholder test register into an SWC. This intermediate step can allow for easy integration of CWCs with existing design tools. Lastly, the SWC can be converted into a CWC by adding a dedicated test register, along with the other circuitry described above.

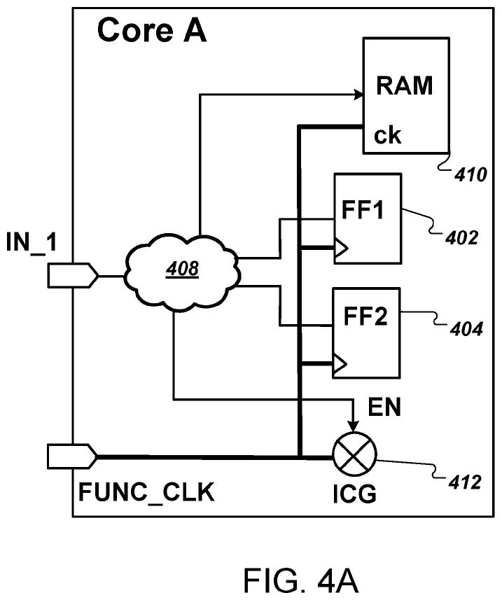

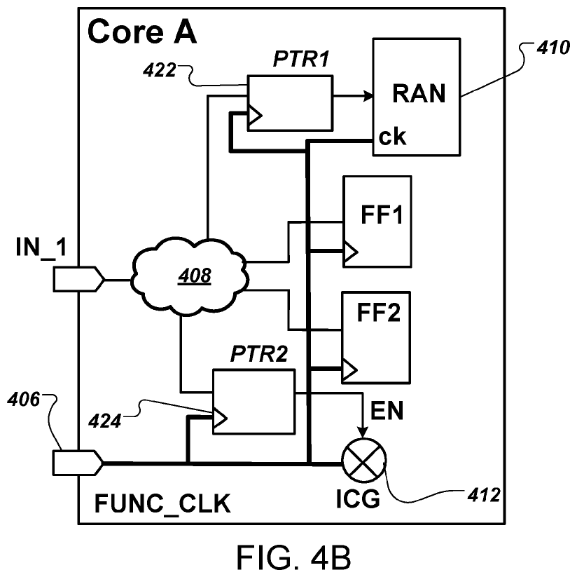

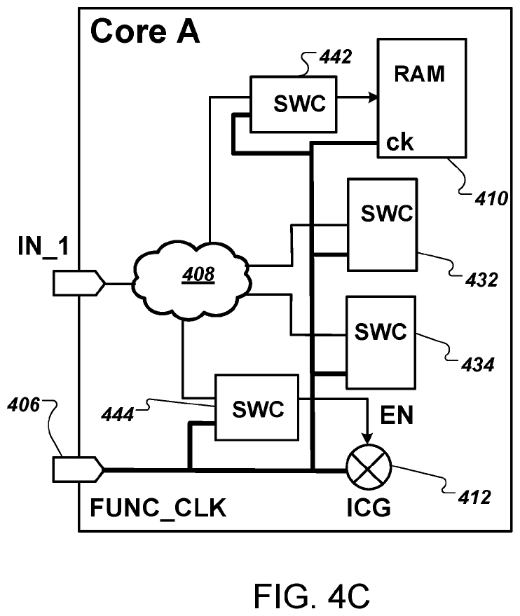

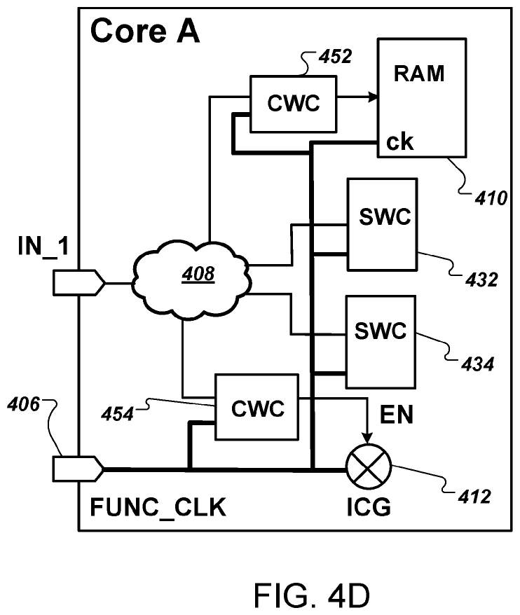

FIGS. 4A, 4B, 4C, and 4D illustrate the stages of an example process for inserting a custom wrapper cell into a hardware design. This is an example of a process that can be performed completely automatically by an EDA tool, appropriately programmed in accordance with this specification. Alternatively or in addition, the example process can be performed with some user input that specifies which NSEs should trigger the insertion of custom wrapper cells.

FIG. 4A illustrates a first stage that involves identifying NSEs. For example, as a precursor to the insertion process, all functional ports which are along synchronous interfaces and have NSE(s) on their fanin/fanout can be identified through a netlist tracing procedure. The corresponding NSEs can be extracted, consolidated and earmarked for subsequent processing.

In this excerpt of the design, there are two such NSEs: a RAM 410, and an ICG 412. The design also has two functional registers 402 and 404 on the fanout of logic 408 for which there are no NSEs. These functional registers can be wrapped with ordinary shared wrapper cells once the NSEs are handled with customer wrapper cells.

FIG. 4B illustrates a second stage that involves inserting placeholder registers. For each NSE identified from the first stage, a placeholder test register can be added at its input by tapping the same functional clock as the NSE in order to prepare the design for custom wrapper insertion. This process converts all the start and end points corresponding to each functional port as scannable registers, which makes it fully compliant to the requirements for the next intermediate stage of SWC insertion.

In this example, two placeholder test registers (PTRs) 422 and 424 are added at the inputs of the RAM 410 and the ICG 412, which both tap into the functional clock signal 406 used by those NSE components.

FIG. 4C illustrates a third stage that involves adding or converting SWCs. A core wrapper insertion command can be performed by setting the required constraints required to enable SWC usage for each functional port. This step converts the functional registers 402 and 404, as well as the placeholder test registers 422 and 424 into SWCs. Thus, the design now has four SWCs, 432, 434, 442, and 444 that are all driven by the same functional clock 406.

FIG. 4D illustrates a final stage that involves converting some SWCs into CWCs. As a final step, the SWCs mapped to the PTRs added onto the NSE(s) can be replaced with CWCs using an automated module swap procedure. As described above, this can involve adding a dedicated test register for each SWC converted into a CWC.

In this example, the SWCs that originated from the PTRs 422 and 424 have been replaced with CWCs 452 and 454.

While the major benefits of the techniques described in this specification allow for the conversion of functional registers to SWCs, which allows true at-speed test on the interface, these techniques also significantly improve the testability on the NSE paths. Besides providing the required isolation, CWC insertion adds controllability and observability on the NSE paths allowing them to be tested at-speed as well. To ensure high quality test of delay faults along NSE paths, clock skew and data path deltas between the tested path and actual functional path ideally need to be zero or as minimal as possible. Typically post final implementation, a CWC is expected to be placed physically closer to an NSE and its clock tapped from the same driver controlling clock input to the NSE. Therefore, the clock skew delta between the CWC and the NSE can be expected to be negligible given the minimal divergence.

When the techniques described in this specification were tested on a system, SC1, having two large subsystems, Core A and Core B, of a multi-billion-gate system on a chip, the at-speed test coverage improved significantly with minimal overhead.

Table 1 summarizes the results of deploying custom wrappers as described in this specification Core A and Core B. Breakup of excluded (nonfunctional and static DFT configuration ports) and targeted ports for wrapper cell insertion out of the total ports are shared for each core.

TABLE 1

| Design SC1 | Core A | Core B |
|---|---|---|
| Total Ports # | 1581 | 5760 |
| Exclude Ports # | 189 | 622 |
| Wrapped Ports # | 1392 | 5138 |
| SWC Ports # | 1263 | 4167 |
| DWC Constant # | 42 | 555 |
| DWC NSE ICG # | 15 | 94 |
| DWC NSE MEM # | 72 | 322 |
| Total NSE # | 87 | 416 |
| NSE % | 6.25% | 8.10% |
| Baseline Test Coverage | 86.46% | 91.59% |
| Proposed Test Coverage | 93.97% | 90.64% |
| Delta | 7.51% | 9.05% |

It may be noted that out of the 100% ports targeted for wrapping, 3.02% and 10.8% ports are defaulted to DWC for CoreA and CoreB respectively due to constant gating internal to the core. Since these are functionally non-excitable paths, it can be safely considered non-critical for SWC usage. Contribution of NSEs (both ICG and memories) causing the tool to default to DWC usage for their corresponding ports are 6.25% (CoreA) and 8.10% (CoreB). Which leaves only 90.7% (CoreA) and 81.1% (CoreB) ports considered for SWC usage in the baseline implementation.

However, the usage of CWC insertion methodology has bridged this gap and resulted in overall improvement of 6.25% and 8.1% in SWC usage. To corroborate the effectiveness, the test coverage from running ATPG specifically targeted on delay faults at the core boundary between baseline and the proposed method is compared. As can be seen, the proposed method has helped in significant transition delay fault coverage improvement at the boundary by 7.51% and 9.05% for CoreA and CoreB respectively.

When tested on another system, SC2, having three cores, Core A, Core B, and Core C, that communicate through a bridge with synchronous data interfaces, using CWCs also significantly improved at-speed testing coverage. Table 2 lists the key statistics and results from deploying the techniques described in this specification on the three cores to enable at-speed delay fault test coverage at the boundary.

TABLE 2

| Design SC2 | Core A | Core B | Core C |
|---|---|---|---|
| Total Ports # | 2674 | 3005 | 2872 |
| Top DWCs # | 2510 | 2770 | 2679 |
| Sync Ports # | 2089 | 1838 | 2247 |
| CTP Ctrl Pins # | 9930 | 10232 | 10623 |
| CTP Regs # | 1790 | 1812 | 1799 |
| CTP Area Overhead | 0.08% | 0.03% | 0.09% |
| Coverage % | 92.70% | 95.80% | 91.92% |

Breakup of synchronous interface ports (Sync Ports #) that required to be tested at-speed and ports wrapped using DWC (Top DWCs #) is shown. An internal layer of isolation is added on the inward facing side of bridges using CTP elements. “CTP Ctrl Pins #” corresponds to the number of internal pins on which CTPs were added. For all the pins identified to require toggle control, register based CTPs (CTP_regs #) were added with a sharing ratio of 3 (1 test register per 3 pins). Compared to the overall core area, overhead due to addition of internal wrapper chain is observed to be very minimal (max 0.09%).

Notably, at-speed delay fault coverage for faults at the core boundary is not feasible in the baseline method due to DWC implementation. However, it is now possible by virtue of the techniques described in this specification, which has resulted in coverage jump from 0% to ˜92-96% coverage, which is quite significant. The fact that this is achieved with a very minimal overhead proves the efficacy of the proposed solution.

This specification uses the term “configured” in connection with systems and computer program components. For a system of one or more computers to be configured to perform particular operations or actions means that the system has installed on it software, firmware, hardware, or a combination of them that in operation cause the system to perform the operations or actions. For one or more computer programs to be configured to perform particular operations or actions means that the one or more programs include instructions that, when executed by data processing apparatus, cause the apparatus to perform the operations or actions.

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non transitory storage medium for execution by, or to control the operation of, data processing apparatus. The computer storage medium can be a machine-readable storage device, a machine-readable storage substrate, a random or serial access memory device, or a combination of one or more of them. Alternatively or in addition, the program instructions can be encoded on an artificially generated propagated signal, e.g., a machine-generated electrical, optical, or electromagnetic signal, that is generated to encode information for transmission to suitable receiver apparatus for execution by a data processing apparatus.

The term “data processing apparatus” refers to data processing hardware and encompasses all kinds of apparatus, devices, and machines for processing data, including by way of example a programmable processor, a computer, or multiple processors or computers. The apparatus can also be, or further include, special purpose logic circuitry, e.g., an FPGA (field programmable gate array) or an ASIC (application specific integrated circuit). The apparatus can optionally include, in addition to hardware, code that creates an execution environment for computer programs, e.g., code that constitutes processor firmware, a protocol stack, a database management system, an operating system, or a combination of one or more of them.

A computer program, which may also be referred to or described as a program, software, a software application, an app, a module, a software module, a script, or code, can be written in any form of programming language, including compiled or interpreted languages, or declarative or procedural languages; and it can be deployed in any form, including as a stand alone program or as a module, component, subroutine, or other unit suitable for use in a computing environment. A program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub programs, or portions of code. A computer program can be deployed to be executed on one computer or on multiple computers that are located at one site or distributed across multiple sites and interconnected by a data communication network.

The processes and logic flows described in this specification can be performed by one or more programmable computers executing one or more computer programs to perform functions by operating on input data and generating output. The processes and logic flows can also be performed by special purpose logic circuitry, e.g., an FPGA or an ASIC, or by a combination of special purpose logic circuitry and one or more programmed computers.

Computers suitable for the execution of a computer program can be based on general or special purpose microprocessors or both, or any other kind of central processing unit. Generally, a central processing unit will receive instructions and data from a read only memory or a random access memory or both. The essential elements of a computer are a central processing unit for performing or executing instructions and one or more memory devices for storing instructions and data. The central processing unit and the memory can be supplemented by, or incorporated in, special purpose logic circuitry. Generally, a computer will also include, or be operatively coupled to receive data from or transfer data to, or both, one or more mass storage devices for storing data, e.g., magnetic, magneto optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer readable media suitable for storing computer program instructions and data include all forms of non volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's device in response to requests received from the web browser. Also, a computer can interact with a user by sending text messages or other forms of message to a personal device, e.g., a smartphone that is running a messaging application, and receiving responsive messages from the user in return.

In addition to the embodiments described above, the following embodiments are also innovative:

Embodiment 1 is a device having one or more wrapper cells for testing functional components of the device, wherein the one or more wrapper cells include a custom wrapper cell having a dedicated test register that is driven by a functional clock, the functional clock being the clock used by at least one of the functional components of the device.

Embodiment 2 is the device of embodiment 1, wherein the custom wrapper cell comprises an inverted loop back path from an output multiplexor of the custom wrapper cell to an input of the dedicated test register.

Embodiment 3 is the device of embodiment 2, wherein the custom wrapper cell comprises an input multiplexor that is configured to select between the dedicated test register receiving a test input or an inverted functional input of the inverted loop back path.

Embodiment 4 is the device of any one of embodiments 1-3, wherein the custom wrapper cell is arranged on a fanin or fanout path of a component that incompatible with a shared wrapper cell (SWC).

Embodiment 5 is the device of embodiment 4, wherein the component that is incompatible with a SWC is a non-scannable sequential element (NSE).

Embodiment 6 is the device of embodiment 5, wherein the NSE is a component that does not have a scan input or scan output for testing.

Embodiment 7 is the device of embodiment 5 or 6, wherein the NSE is a random-access memory.

Embodiment 8 is the device of embodiment 5 or 6, wherein the NSE is an integrated clock gating cell.

Embodiment 9 is the device of any one of embodiments 5 to 8, wherein the fanout path having the NSE includes one or more functional registers that are wrapped with shared wrapper cells.

Embodiment 10 is the device of any one of embodiments 1-9, wherein the functional clock of the custom wrapper cell operates at a faster speed than a test clock used by dedicated wrapper cells.

Embodiment 11 is a method for generating a design for testing having a custom wrapper cell, the method comprising:
receiving a hardware design having one or more functional components;
determining that the hardware design has a functional component that is incompatible with a shared wrapper cell (SWC);
adding a placeholder test register on a path to the functional component that is incompatible with a SWC; and
converting the placeholder test register to a custom wrapper cell.

Embodiment 12 is the method of embodiment 11, wherein the custom wrapper cell has a dedicated test register that is driven by a functional clock, the functional clock being the clock used by the functional component that is incompatible with a SWC.

Embodiment 13 is the method of embodiment 12, wherein the functional clock of the custom wrapper cell operates at a faster speed than a test clock used for dedicated wrapper cells.

Embodiment 14 is the method of embodiment 12 or 13, wherein the custom wrapper cell comprises an inverted loop back path from an output multiplexor of the custom wrapper cell to an input of the dedicated test register.

Embodiment 15 is the method of embodiment 14, wherein the custom wrapper cell an input multiplexor that is configured to select between the dedicated test register receiving a test input or an inverted functional input of the inverted loop back path.

Embodiment 16 is the method of any one of embodiments 11-15, wherein adding the placeholder test register comprises tapping a same functional clock as the component that is incompatible with a SWC.

Embodiment 17 is the method of any one of embodiments 11-16, wherein the component that is incompatible with a SWC is a non-scannable sequential element (NSE).

Embodiment 18 is the method of embodiment 17, wherein the NSE is a component that does not have a scan input or scan output for testing.

Embodiment 19 is the method of embodiment 17 or 18, wherein the NSE is a random access memory.

Embodiment 20 is the method of embodiment 17 or 18, wherein the NSE is an integrated clock gating cell (ICG).

Embodiment 21 is the method of any one of embodiments 11-20, further comprising converting one or more functional registers on a fanin or fanout path of the component that is incompatible with a SWC into respective shared wrapper cells having functional registers driven by a functional clock.

Embodiment 22 is a system comprising: one or more computers and one or more storage devices storing instructions that are operable, when executed by the one or more computers, to cause the one or more computers to perform the method of any one of claims 11 to 21.

Embodiment 23 is a computer storage medium encoded with a computer program, the program comprising instructions that are operable, when executed by data processing apparatus, to cause the data processing apparatus to perform the method of any one of claims 11 to 21.

Embodiment 24 is a method comprising performing a testing process using the device of any one of embodiments 1-10.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

What is claimed is:

1. A device having one or more wrapper cells for testing functional components of the device, wherein the one or more wrapper cells include a custom wrapper cell having a dedicated test register that is driven by a functional clock, the functional clock being the clock used by at least one of the functional components of the device.

2. The device of claim 1, wherein the custom wrapper cell comprises an inverted loop back path from an output multiplexor of the custom wrapper cell to an input of the dedicated test register.

3. The device of claim 2, wherein the custom wrapper cell comprises an input multiplexor that is configured to select between the dedicated test register receiving a test input or an inverted functional input of the inverted loop back path.

4. The device of claim 1, wherein the custom wrapper cell is arranged on a fanin or fanout path of a component that incompatible with a shared wrapper cell (SWC).

5. The device of claim 4, wherein the component that is incompatible with a SWC is a non-scannable sequential element (NSE).

6. The device of claim 5, wherein the NSE is a component that does not have a scan input or scan output for testing.

7. The device of claim 5, wherein the NSE is a random-access memory.

8. The device of claim 5, wherein the NSE is an integrated clock gating cell.

9. The device of claim 5, wherein the fanout path having the NSE includes one or more functional registers that are wrapped with shared wrapper cells.

10. The device of claim 1, wherein the functional clock of the custom wrapper cell operates at a faster speed than a test clock used by dedicated wrapper cells.

11. A method for generating a design for testing having a custom wrapper cell, the method comprising:
receiving a hardware design having one or more functional components;
determining that the hardware design has a functional component that is incompatible with a shared wrapper cell (SWC);
adding a placeholder test register on a path to the functional component that is incompatible with a SWC; and
converting the placeholder test register to a custom wrapper cell.

12. The method of claim 11, wherein the custom wrapper cell has a dedicated test register that is driven by a functional clock, the functional clock being the clock used by the functional component that is incompatible with a SWC.

13. The method of claim 12, wherein the functional clock of the custom wrapper cell operates at a faster speed than a test clock used for dedicated wrapper cells.

14. The method of claim 12, wherein the custom wrapper cell comprises an inverted loop back path from an output multiplexor of the custom wrapper cell to an input of the dedicated test register.

15. The method of claim 14, wherein the custom wrapper cell an input multiplexor that is configured to select between the dedicated test register receiving a test input or an inverted functional input of the inverted loop back path.

16. The method of claim 11, wherein adding the placeholder test register comprises tapping a same functional clock as the component that is incompatible with a SWC.

17. The method of claim 11, wherein the component that is incompatible with a SWC is a non-scannable sequential element (NSE).

18. The method of claim 17, wherein the NSE is a component that does not have a scan input or scan output for testing.

19. The method of claim 17, wherein the NSE is a random access memory.

20. (canceled)

21. The method of claim 11, further comprising converting one or more functional registers on a fanin or fanout path of the component that is incompatible with a SWC into respective shared wrapper cells having functional registers driven by a functional clock.

22-24. (canceled)
